(19) United States
(12) Patent Application Publication
(10) Pub. No.: US 2025/0045502 A1
(43) Pub. Date: Feb. 6, 2025

(54) HUB CHIPLET AND HUB CHIPLET PACKAGE

(71) Applicant: Primemas Inc., New York, NY (US)

(72) Inventors: Il PARK, Seoul (KR); Jaegeun YUN, Seongnam-si Gyeonggi-do (KR); Dukho JEON, Seoul (KR); Vladimir KORNIJCUK, Seoul (KR); Jinsu PARK, Hwaseong-si Gyeonggi-do (KR); Seungbae KANG, Seoul (KR)

(73) Assignee: Primemas Inc., New York, NY (US)

(21) Appl. No.: 18/602,236

(22) Filed: Mar. 12, 2024

Related U.S. Application Data
(60) Provisional application No. 63/530,089, filed on Aug. 1, 2023.

(51) Int. Cl. G06F 30/392; G06F 30/327; G06F 30/33

(52) U.S. Cl. CPC G06F 30/392; G06F 30/327; G06F 30/33

(57) ABSTRACT

A hub chiplet includes a functional module. The hub chiplet includes a top connection module formed on a cross-section of the hub chiplet in a first direction; a bottom connection module formed on a cross-section of the hub chiplet in a second direction opposite to the first direction; a left connection module formed on a cross-section of the hub chiplet in a third direction perpendicular to a first straight line connecting the top connection module to the bottom connection module; and a right connection module formed on a cross-section of the hub chiplet in a fourth direction that is perpendicular to the first straight line and is opposite to the third direction. The top connection module is connectable to the bottom connection module through a device-to-device (D2D) connection, and the left connection module is connectable to the right connection module through the D2D connection.

### CROSS-REFERENCE TO RELATED APPLICATION

This application claims the benefit of U.S. Provisional Application No. 63/530,089 filed on Aug. 1, 2023, the entire contents of which are herein incorporated by reference.

### BACKGROUND

### 1. Field

The present disclosure relates to a hub chiplet and a hub chiplet package. Particularly, the present disclosure relates to a hub chiplet using a chiplet structure and a hub chiplet package including the hub chiplet.

### 2. Description of the Related Art

Over the past few years, artificial intelligence (AI) technology has been mentioned as the most promising technology worldwide and a core technology of the fourth Industrial Revolution. The biggest problem of the artificial intelligence technology is computing performance. The most important thing of the artificial intelligence technology that realizes human learning, reasoning, perception, and natural language translation abilities is to quickly process lots of data.

The semiconductor industry has developed so far by reducing the size of a line width, making chips smaller, achieving integration, and reducing power consumption. However, as the technology reaches a physical limit of reducing the size of the line width, the difficulty of a semiconductor manufacturing process rapidly increases, and as a distance between circuits is reduced, various problems occurs, such as lower yield due to leakage current.

Accordingly, semiconductor companies are paying attention to chiplet that is a post-process packaging technology connecting multiple chips into one to reduce costs. This chiplet is a technology to manufacture a single chip (or system-on-chip) by combining sub-modules with various functions, and each sub-module functions as a material that may not operate alone, but may be freely expanded and combined, and in this respect, the chiplet is different from the existing chip (or system-on-chip) structure.

### SUMMARY

The present disclosure provides a hub chiplet having a freely expandable chiplet structure.

Also, the present disclosure provides a hub chiplet package having a freely expandable chiplet structure.

Objects of the present disclosure are not limited to the objects described above, and other objects and advantages of the present disclosure that are not described may be understood by following descriptions and will be more clearly understood by examples of the present disclosure. Also, it will be apparent that objects and advantages of the present disclosure may be realized by devices and combinations thereof indicated in patent claims.

A hub chiplet and hub chiplet package of the present disclosure may be freely expanded through a chiplet structure.

Also, the object may be achieved by a combination of hub chiplets without the need to develop a new system-on-chip device to increase a scale.

According to some aspects of the disclosure, a hub chiplet including a functional module, the hub chiplet comprises, a top connection module formed on a cross-section of the hub chiplet in a first direction, a bottom connection module formed on a cross-section of the hub chiplet in a second direction opposite to the first direction, a left connection module formed on a cross-section of the hub chiplet in a third direction perpendicular to a first straight line connecting the top connection module to the bottom connection module; and a right connection module formed on a cross-section of the hub chiplet in a fourth direction that is perpendicular to the first straight line and is opposite to the third direction, wherein the top connection module is connectable to the bottom connection module through a device-to-device (D2D) connection, and the left connection module is connectable to the right connection module through the D2D connection.

According to some aspects, the right connection module is couplable to the left connection module in which the first direction and the second direction are reversed.

According to some aspects, the left connection module is couplable to the right connection module in which the first direction and the second direction are reversed.

According to some aspects, the top connection module is couplable to the bottom connection module in which the third direction and the fourth direction are reversed.

According to some aspects, the bottom connection module is couplable to the top connection module in which the third direction and the fourth direction are reversed.

According to some aspects, the functional module is at least one of a processor, a memory controller, a D2D interface, a resource scheduler, a security engine, a debug interface, and a peripheral logic circuit.

According to some aspects, the top connection module, the bottom connection module, the left connection module, and the right connection module are each couplable to a custom logic die that operates like the hub chiplet.

According to some aspects of the disclosure, a hub chiplet package comprises, a first hub chiplet and a second hub chiplet having the same shape as each other and connected to each other through a D2D connection, a first custom logic die connected to the first hub chiplet through the D2D connection, and a second custom logic die connected to the second hub chiplet through the D2D connection, wherein a system-on-chip (SoC) is operated by the first hub chiplet, the second hub chiplet, the first custom logic die, and the second custom logic die.

According to some aspects, the first hub chiplet includes a first processor and a first memory controller, and the first custom logic die includes a first memory controlled by the first memory controller.

According to some aspects, the second hub chiplet includes a second processor and a second memory controller, and the second custom logic die includes a second memory controlled by the second memory controller.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the above descriptions, detailed effects of the present disclosure are described below while describing details for implementing the present disclosure.

### BRIEF DESCRIPTION OF THE DRAWINGS

FIG. 1 is a conceptual diagram illustrating a hub chiplet according to some embodiments of the present disclosure.

FIG. 2 is a diagram illustrating the D2D interface 150 of the hub chiplet 100 of FIG. 1.

FIGS. 3 to 8 are diagrams illustrating D2D connection types of a hub chiplet according to some embodiments of the present disclosure.

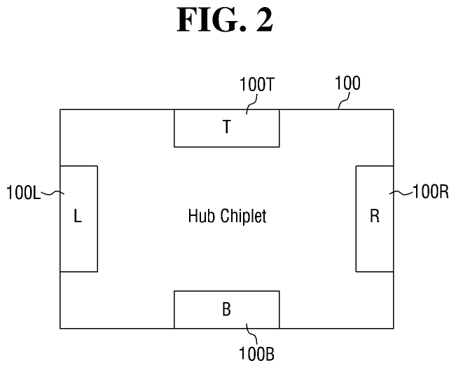

FIG. 2 and FIGS. 9 to 11 are diagrams illustrating package types of hub chiplets according to some embodiments of the present disclosure.

FIG. 12 is a flowchart illustrating a method of manufacturing a hub chiplet package, according to some embodiments of the present disclosure.

FIG. 13 is a view illustrating a method of scaling up a hub chiplet package, according to some embodiments of the present disclosure.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains. Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

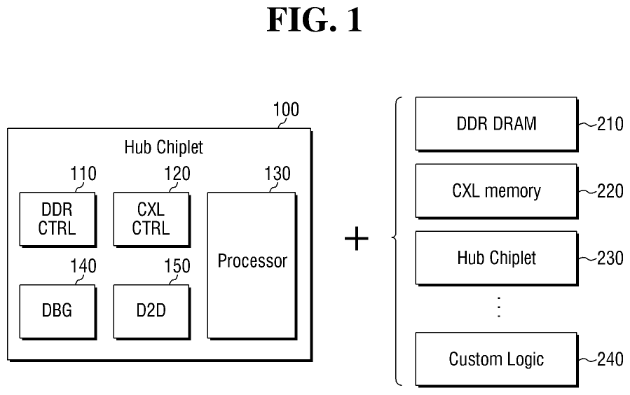

Hereinafter, a hub chiplet according to some embodiments of the present disclosure will be described with reference to FIGS. 1 to 11.

FIG. 1 is a conceptual diagram illustrating a hub chiplet according to some embodiments of the present disclosure.

Referring to FIG. 1, a hub chiplet 100 according to some embodiments of the present disclosure may be a type of semiconductor chiplet. A chiplet is a small type of chip and may be a unit module that is relatively small and performs a specific function unlike an integrated circuit chip. The chiplet may be mainly used to build a larger system through communication and connection between various devices.

The hub chiplet 100 may include various function modules therein. In this case, a functional module may include at least one of a processor 130, memory controllers 110 and 120, a device-to-device (D2D) interface 150, a resource scheduler, a security engine, a debug interface 140, and a peripheral logic circuit. In this case, the processor 130 may be at least one of a central processing unit (CPU), a graphics processing unit (GPU), and a neural processing unit (NPU). However, the present embodiment is not limited thereto.

The memory controllers 110 and 120 may include, for example, a DDR controller 110 that controls double data rate synchronous dynamic random-access memory (DDR DRAM) 210 and a compute express link (CXL) controller 120 that controls a CXL memory 220. However, the present embodiment is not limited thereto, and the memory controllers 110 and 120 may include a static random access memory (SRAM) controller, a single data rate (SDR) controller that controls SDR DRAM, or another type of memory controller, such as a PCIe host interface.

The D2D interface 150 may physically connect the hub chiplet 100 to another device to exchange data and signals therebetween. The hub chiplet 100 may be coupled to other devices through the D2D interface 150 to build a system-on-chip (SoC) package. For example, hub chiplets 230 and a custom logic die 240 required for other systems may be coupled to the hub chiplet 100 through the D2D interface 150.

The resource scheduler may determine how to distribute and schedule power and frequency of each functional block. The resource scheduler may be implemented by hardware or software.

The security engine may perform operations related to the security of the hub chiplet 100 and a package system including the hub chiplet 100. That is, the security engine may perform validation check and security check through a tamper-proof memory, such as a root of trust. However, the present embodiment is not limited thereto.

The debug interface 140 may monitor and debug operations of the hub chiplet 100 and the software/hardware of a package system including the hub chiplet 100. Therethrough, the debug interface 140 may correct operations of the hub chiplet 100 when the hub chiplet 100 performs an abnormal operation.

The peripheral logic circuit may refer to various logic circuits other than the functional blocks described above. For example, the peripheral logic circuit may include at least one of a serial communication interface that supports serial communication protocols, such as universal asynchronous receiver-transmitter (UART), serial peripheral interface (SPI), and inter-integrated circuit (I2C), a general-purpose input)/output (GPIO) pin, a timer, a counter, a direct memory access (DMA) controller, an interrupt controller, and an analog interface.

The hub chiplet 100 may be connected to various custom logic dies through the various functional blocks described above to build the entire hub chiplet package. Specifically, the hub chiplet 100 may be coupled to at least one of the DDR DRAM 210, the CXL memory 220, another hub chiplet 230, and the custom logic die 240. Through the easy expansion, the hub chiplet 100 may easily derive a configuration of the entire system by coupling multiple module devices to each other.

FIG. 2 is a diagram illustrating the D2D interface 150 of the hub chiplet 100 of FIG. 1.

Referring to FIG. 2, the hub chiplet 100 may include one or more D2D connectors to be connected to other devices. The D2D connectors may be arranged in four directions on a plane, as illustrated in FIG. 2.

Specifically, the hub chiplet 100 may include a top connection module 100T in an upper cross-section on the plane of the hub chiplet 100, a bottom connection module 100B in a lower cross-section on the plane of the hub chiplet 100, a left connection module 100L in a left cross-section on the plane of the hub chiplet 100, and a right connection module 100R in a right cross-section on the plane of the hub chiplet 100.

In this case, the top connection module 100T and the bottom connection module 100B may be arranged in cross-sections in opposite directions, and the left connection module 100L and the right connection module 100R may be arranged in cross-sections in opposite directions. Also, a first straight line connecting the top connection module 100T to the bottom connection module 100B and a second straight line connecting the left connection module 100L to the right connection module 100R are not parallel to each other but intersect each other. Furthermore, the first straight line may also be perpendicular to the second straight line. However, the present embodiment is not limited thereto.

The top connection module 100T, the bottom connection module 100B, the left connection module 100L, and the right connection module 100R may be connected to connection modules of other hub chiplets 230 to be physically connected between hub chiplets 100. Therethrough, routing of data and signals may be performed between the hub chiplets 100. In this case, signals may be transmitted quickly without delay between various functional modules, and thus, processing speed of the entire package may be increased.

Also, although FIG. 2 illustrates the hub chiplet 100 of a rectangle and four connection modules respectively arranged on four sides, the present embodiment is not limited thereto. The present embodiment may include a shape in which multiple hub chiplets 100 are aligned with each other and may be easily coupled to each other by using a D2D connection. Also, as long as the conditions are satisfied, the number of connection modules included in one hub chiplet 100 may be changed.

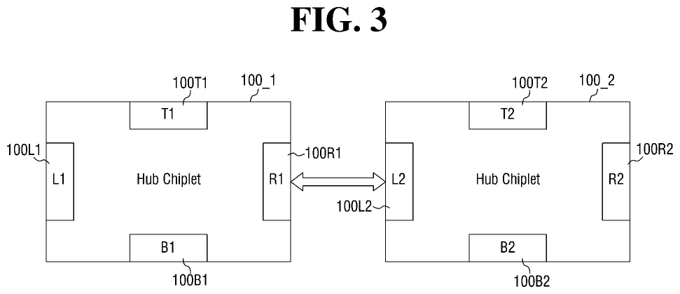

FIGS. 3 to 8 are diagrams illustrating D2D connection types of a hub chiplet according to some embodiments of the present disclosure.

Referring to FIG. 3, a first hub chiplet 100_1 and a second hub chiplet 100_2 may be connected to each other through a D2D connection. The first hub chiplet 100_1 may include a first top connection module 100T1, a first bottom connection module 100B1, a first left connection module 100L1, and a first right connection module 100R1. The second hub chiplet 100_2 may include a second top connection module 100T2, a second bottom connection module 100B2, a second left connection module 100L2, and a second right connection module 100R2.

In this case, the first top connection module 100T1 may have the same shape as the second top connection module 100T2, and the first bottom connection module 100B1 may have the same shape as the second bottom connection module 100B2. Similarly, the first left connection module 100L1 may have the same shape as the second left connection module 100L2, and the first right connection module 100R1 may have the same shape as the second right connection module 100R2.

The first right connection module 100R1 may be connected to the second left connection module 100L2 through a D2D connection. That is, the first right connection module 100R1 and the first left connection module 100L1 may have shapes couplable to each other. Likewise, the second right connection module 100R2 and the second left connection module 100L2 may have shapes couplable to each other.

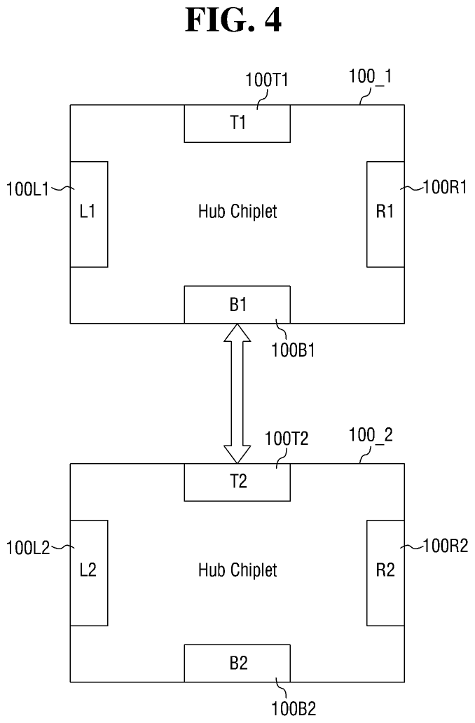

Referring to FIG. 4, the first bottom connection module 100B1 may be connected to the second top connection module 100T2 through a D2D connection. That is, the first bottom connection module 100B1 and the first top connection module 100T1 may have shapes couplable to each other. Likewise, the second bottom connection module 100B2 and the second top connection module 100T2 may have shapes couplable to each other.

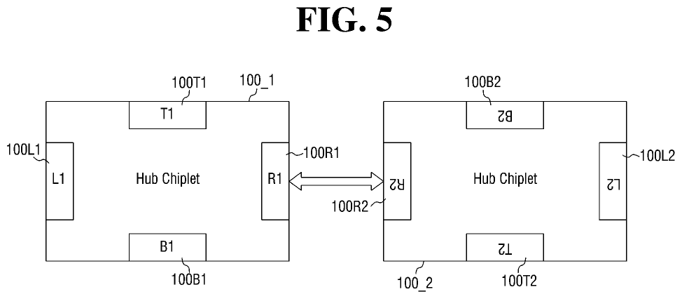

Referring to FIG. 5, the first right connection module 100R1 may be connected to the second right connection module 100R2 in a state where the second hub chiplet 100_2 is upside down. In this case, a first direction in which the first top connection module 100T1 and the first bottom connection module 100B1 of the first hub chiplet 100_1 are sequentially arranged may be opposite to a second direction in which the second top connection module 100T2 and the second bottom connection module 100B2 of the second hub chiplet 100_2 are sequentially arranged.

To this end, although the first right connection module 100R1 is arranged in the first direction or the second direction, the first right connection module 100R1 may be in the same shape. However, the present embodiment is not limited thereto.

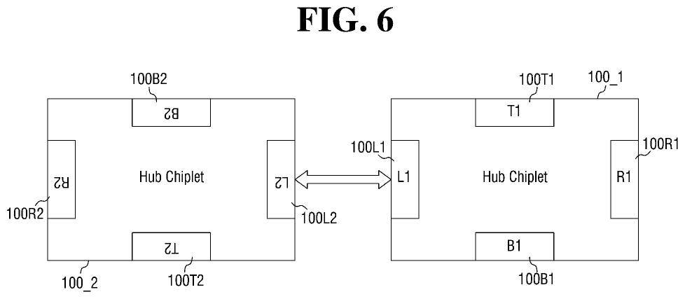

Referring to FIG. 6, the first left connection module 100L1 may be connected to the second left connection module 100L2 in a state where the second hub chiplet 100_2 is upside down. In this case, a first direction in which the first top connection module 100T1 and the first bottom connection module 100B1 of the first hub chiplet 100_1 are sequentially arranged may be opposite to a second direction in which the second top connection module 100T2 and the second bottom connection module 100B2 of the second hub chiplet 100_2 are sequentially arranged.

To this end, although the first left connection module 100L1 is arranged in the first direction or the second direction, the first left connection module 100L1 may be in the same shape. However, the present embodiment is not limited thereto.

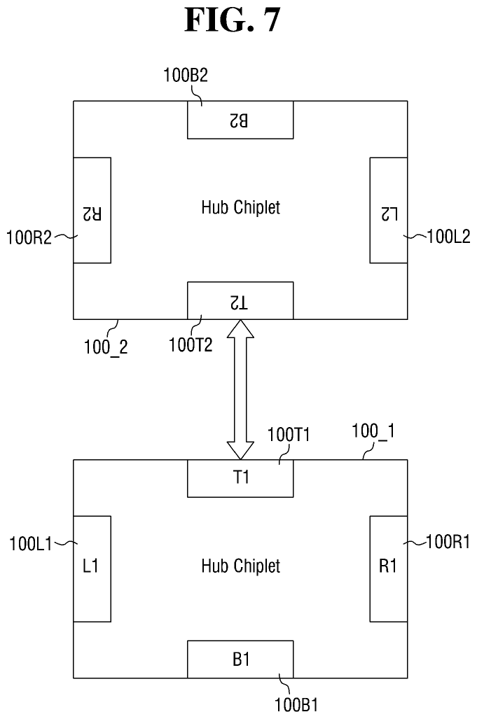

Referring to FIG. 7, the first top connection module 100T1 may be connected to the second top connection module 100T2 in a state where the second hub chiplet 100_2 is upside down. In this case, a third direction in which the first left connection module 100L1 and the first right connection module 100R1 of the first hub chiplet 100_1 are sequentially arranged may be opposite to a fourth direction in which the second left connection module 100L2 and the second right connection module 100R2 of the second hub chiplet 100_2 are sequentially arranged.

To this end, although the first top connection module 100T1 is arranged in the third direction or the fourth direction, the first top connection module 100T1 may be in the same shape. However, the present embodiment is not limited thereto.

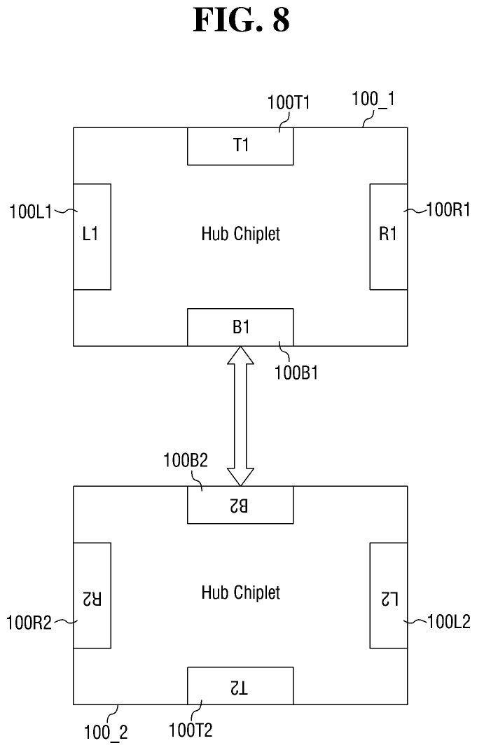

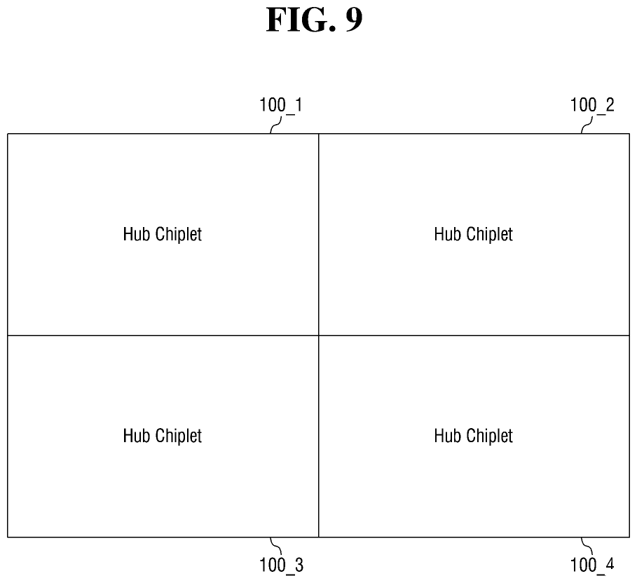

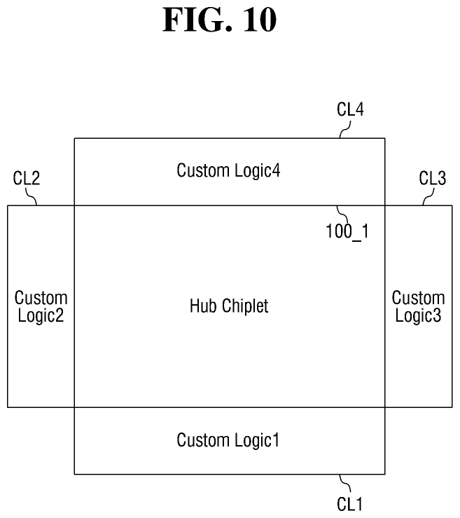

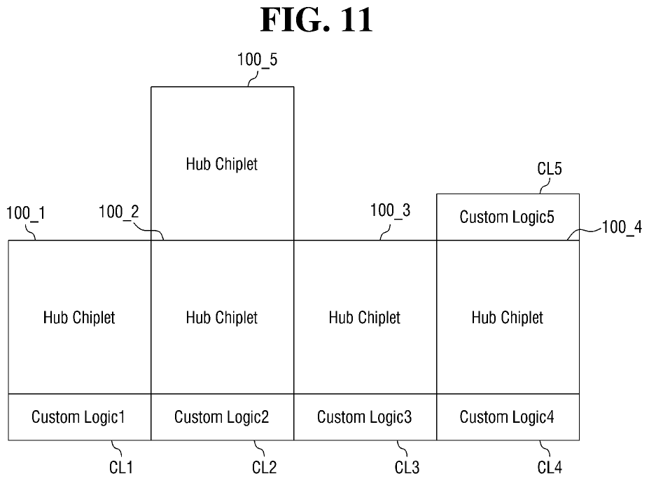

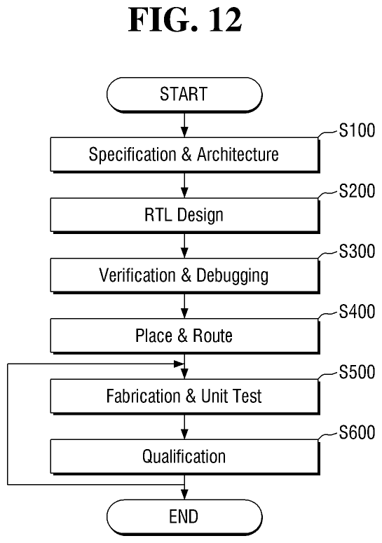

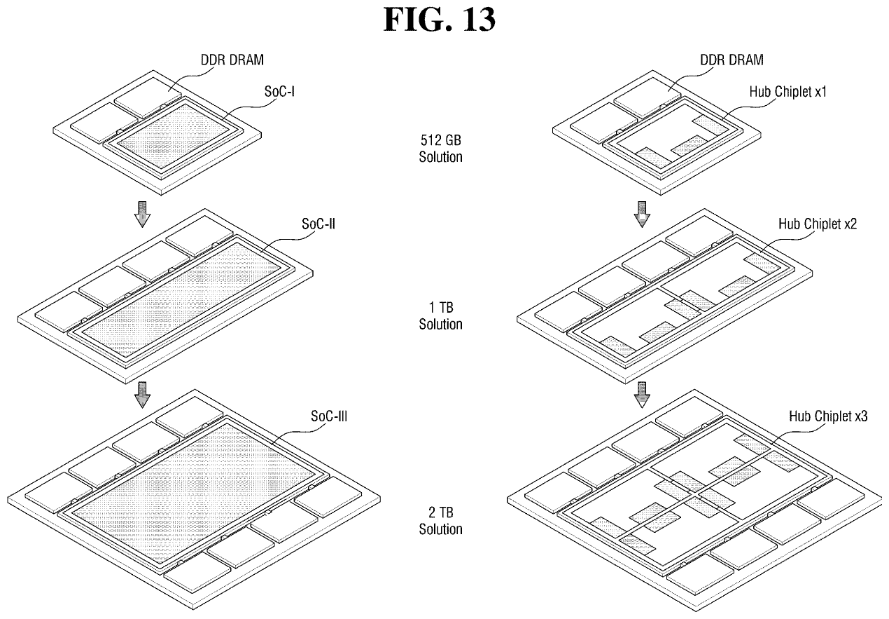

Referring to FIG. 8, the first bottom connection module 100B1 may be connected to the second bottom connection module 100B2 in a state where the second hub chiplet 100_2 is upside down. In this case, the third direction in which the first left connection module 100L1 and the first right connection module 100R1 of the first hub chiplet 100_1 are sequentially arranged may be opposite to the fourth direction in which the second left connection module 100L2 and the second right connection module 100R2 of the second hub chiplet 100_2 are sequentially arranged.

To this end, although the first bottom connection module 100B1 is arranged in the third direction or the fourth direction, the first bottom connection module 100B1 may be in the same shape. However, the present embodiment is not limited thereto.

FIG. 2 and FIGS. 9 to 11 are diagrams illustrating package types of hub chiplets according to some embodiments of the present disclosure.

Referring to FIG. 2, a hub chiplet package may be built with only one hub chiplet 100. That is, when multiple function modules in the hub chiplet 100 may operate as one SoC, the hub chiplet package may be completed.

Referring to FIG. 9, a hub chiplet package may be built with multiple hub chiplets. For example, one hub chiplet package may be built by including a first hub chiplet 100_1, a second hub chiplet 100_2, a third hub chiplet 100_3, and a fourth hub chiplet 100_4 which are connected to each other through a D2D connection.

Referring to FIG. 10, at least one custom logic die may be coupled to one hub chiplet. For example, a first custom logic die CL1, a second custom logic die CL2, a third custom logic die CL3, and a fourth custom logic die CL4 may be coupled to the first hub chiplet 100_1. In this case, the number of custom logic dies may be changed. In this case, the respective custom logic dies may also have the same configuration or different configurations from each other.

That is, the hub chiplet package may be built to perform necessary functions not only by being coupled to similar hub chiplets but also through various custom logic dies.

Referring to FIG. 11, a hub chiplet package according to some embodiments of the present disclosure may be built by a combination of at least one hub chiplet and at least one custom logic die. For example, as illustrated in FIG. 11, first to fourth hub chiplets 100_1 to 100_4 may be consecutively connected in a horizontal direction through a D2D connection. Also, first to fourth custom logic dies CL1 to CL4 may be connected to each other in a horizontal direction respectively below the first to fourth hub chiplets 100_1 to 100_4 Furthermore, a fifth hub chiplet 100_5 may be disposed above the second hub chiplet 100_2 to be coupled to the second hub chiplet 100_2, and a fifth custom logic die CL5 may be disposed above the fourth hub chiplet 100_4 to be coupled to the fourth hub chiplet 100_4.

That is, the hub chiplet package of the present embodiment may very easily configure necessary functions by various combinations of the hub chiplets and the custom logic dies. Also, combinations thereof may be very easily made, and accordingly, it is very simple to configure a package having necessary functions.

FIG. 12 is a flowchart illustrating a method of manufacturing a hub chiplet package, according to some embodiments of the present disclosure.

Referring to FIG. 12, in order to manufacture a hub chiplet, a requirement definition step and a design step are first performed at S100.

The requirement definition step may be a step that requires decisions on several requirements, such as a function that a hub chiplet package has to perform, performance, power consumption, a size, and costs. The design step may be a step in which main functional modules of a package are defined based on the above requirements and a communication method therebetween is determined.

Next, a register-transfer level (RTL) design step is performed at S200.

In this step, a digital logic circuit is designed based on the above requirements and design, and an interaction and data processing of respective components are defined. Next, the digital logic circuit may be converted into a register transfer level, and a data flow and control path may be set.

Next, verification and debugging steps are performed at S300.

The verification step may be a step of checking whether an operation may be performed based on an RTL design. The debugging step may be a step of resolving and optimizing a problem through hardware debugging and software debugging.

Next, placement and route steps are performed at S400.

The placement step may be a step of physically placing logic elements, such as gates, registers, and memory cells, on a semiconductor. In this case, the placement step may be performed by considering a physical size, and so on. In this case, connections between logical elements may also be placed, and a power network may also be placed.

The route step may be a step of implementing and wiring connections between logical elements in an actual layout. In this step, wiring may be made to transmit signals in an electrically optimized manner.

Next, fabrication and unit test steps are performed at S500.

The manufacturing step may be a step of converting the layout completed in the placement and route step into a semiconductor hub chiplet through an actual microprocess step on a semiconductor wafer. The hub chiplet and hub chiplet package of this embodiment may be manufactured through various processes, such as lithography, etching, and deposition.

The unit test step may be a step to testing whether respective module portions of the hub chiplet package perform normal operation. Several types of tests, such as a functional test, a performance test, and a power consumption test may be performed. Next, a qualification step is performed at S600.

The qualification step may be a step of checking whether the completed hub chiplet package satisfies quality and reliability standards. An environmental test, a lifespan test, and a reliability test may be performed during the qualification step.

In this way, the hub chiplet package may be manufactured through multiple steps like the existing semiconductor packages.

FIG. 13 is a view illustrating a method of scaling up a hub chiplet package, according to some embodiments of the present disclosure.

Referring to FIGS. 12 and 13, a difference between the existing SoC and the method of scaling up the hub chiplet package of the present embodiment may be checked. The left side of FIG. 13 illustrates a method of scaling up the existing SoC. In order to increase the memory capacity from 512 GB to 1 TB and 2 TB, step S100 to step S600 in FIG. 12 have to be repeated each time.

Specifically, even when the production of SoC—is completed, the production of SoC-II and SoC-III has to be started again from S100. That is, the manufacturing process period of the existing SoC may be very long and manufacturing costs may be increased. The current approximate production period of the existing SoC may be 24 to 30 months but may be longer.

In contrast to this, when building an SoC by using a hub chiplet package according to some embodiments of the present disclosure, after initially performing step S100 to step S600, only by performing step S500 and step S600 again, scale-up may be easily performed. That is, functional modules required for building a low-scale SoC are already equipped in the existing hub chiplet, and accordingly, the production of a large-scale SoC may be completed simply by increasing quantity. For example, the scale-up may be completed by including one hub chiplet in 512 GB, two hub chiplets in 1 TB, and four hub chiplets in 2 TB. That is, when manufacturing hub chiplets, by adjusting only the number of hub chiplets, step S100 to step S400 may be omitted, and thus, the manufacturing period and costs may be miniaturized. Expected manufacturing speeds are approximately 5 to 10 times the manufacturing speeds of the existing processes, and certain processes may be even faster.

In addition to the expansion of memory capacity in FIG. 13, even in a case where a processor for AI computation is added, the process may naturally be performed quickly by using the scale-up method. In this case, larger and more complex structures may be easily built by merging a D2D connecting and ab off-chip switch interface.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A hub chiplet including a functional module, the hub chiplet comprising:
a top connection module formed on a cross-section of the hub chiplet in a first direction;
a bottom connection module formed on a cross-section of the hub chiplet in a second direction opposite to the first direction;
a left connection module formed on a cross-section of the hub chiplet in a third direction perpendicular to a first straight line connecting the top connection module to the bottom connection module; and
a right connection module formed on a cross-section of the hub chiplet in a fourth direction that is perpendicular to the first straight line and is opposite to the third direction,
wherein the top connection module is connectable to the bottom connection module through a device-to-device (D2D) connection, and
the left connection module is connectable to the right connection module through the D2D connection.

2. The hub chiplet of claim 1, wherein
the right connection module is couplable to the left connection module in which the first direction and the second direction are reversed.

3. The hub chiplet of claim 1, wherein
the left connection module is couplable to the right connection module in which the first direction and the second direction are reversed.

4. The hub chiplet of claim 1, wherein
the top connection module is couplable to the bottom connection module in which the third direction and the fourth direction are reversed.

5. The hub chiplet of claim 1, wherein
the bottom connection module is couplable to the top connection module in which the third direction and the fourth direction are reversed.

6. The hub chiplet of claim 1, wherein
the functional module is at least one of a processor, a memory controller, a D2D interface, a resource scheduler, a security engine, a debug interface, and a peripheral logic circuit.

7. The hub chiplet of claim 1, wherein
the top connection module, the bottom connection module, the left connection module, and the right connection module are each couplable to a custom logic die that operates like the hub chiplet.

8. A hub chiplet package comprising:
a first hub chiplet and a second hub chiplet having the same shape as each other and connected to each other through a D2D connection;
a first custom logic die connected to the first hub chiplet through the D2D connection; and
a second custom logic die connected to the second hub chiplet through the D2D connection,
wherein a system-on-chip (SoC) is operated by the first hub chiplet, the second hub chiplet, the first custom logic die, and the second custom logic die.

9. The hub chiplet package of claim 8, wherein
the first hub chiplet includes a first processor and a first memory controller, and
the first custom logic die includes a first memory controlled by the first memory controller.

10. The hub chiplet package of claim 9, wherein
the second hub chiplet includes a second processor and a second memory controller, and
the second custom logic die includes a second memory controlled by the second memory controller.
